(19) United States
(12) Patent Application Publication
(10) Pub. No.: US 2025/0105793 A1
(43) Pub. Date: Mar. 27, 2025

(54) DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/829,720

(22) Filed: Sep. 10, 2024

(30) Foreign Application Priority Data
Sep. 22, 2023 (JP) 2023-158175

(51) Int. Cl. H03F 1/02; H03F 3/24; H03F 3/45

(52) U.S. Cl. CPC H03F 1/0288; H03F 3/245; H03F 3/45475; H03F 2200/451

(57) ABSTRACT

A first bias circuit, a second bias circuit, a first differential amplifier, a second differential amplifier, and an inverting amplifier are included. The first bias circuit has: a first bias output terminal from which first bias current or a voltage is output to a carrier amplifier; and a first monitoring terminal from which a first monitoring signal is output. The second bias circuit has: a second bias output terminal from which second bias current or a voltage is output to a peaking amplifier; and a second monitoring terminal from which a second monitoring signal is output. The first differential amplifier outputs the first bias control signal. The second differential amplifier outputs an amplified signal. The inverting amplifier outputs the second bias control signal resulting from inverting amplification of the amplified signal.

### CROSS REFERENCE TO RELATED APPLICATION

This application claims priority from Japanese Patent Application No. 2023-158175 filed on Sep. 22, 2023. The content of this application is incorporated herein by reference in its entirety.

### BACKGROUND

The present disclosure relates to a Doherty amplifier circuit.

A Doherty amplifier circuit is known as a highly efficient power amplifier circuit. The Doherty amplifier circuit typically has a configuration in which a carrier amplifier and a peaking amplifier are connected in parallel, the carrier amplifier operating regardless of the power level of an input signal, the peaking amplifier turning off if the power level of the input signal is low and turning on if the power level is high. In the configuration, if the power level of a radio-frequency input signal is high, the carrier amplifier operates with saturation being kept with a saturation output power level. The Doherty amplifier circuit may thereby have higher efficiency than a general power amplifier circuit.

U.S. Patent Application Publication No. 2016/0241209 below describes technology for controlling the bias of a peaking amplifier. By the technology described in U.S. Patent Application Publication No. 2016/0241209, saturation of a carrier amplifier is detected by the bias circuit of the carrier amplifier, and a bias circuit of the peaking amplifier is controlled in accordance with a detection signal.

### BRIEF SUMMARY

It is difficult for the technology described in U.S. Patent Application Publication No. 2016/0241209 to activate the peaking amplifier in response to a slight increase in the drive level of the carrier amplifier. That is, it is difficult to operate the peaking amplifier with high sensitivity by using the technology described in U.S. Patent Application Publication No. 2016/0241209. It is thus difficult for the technology described in U.S. Patent Application Publication No. 2016/0241209 to keep high the quality of a radio-frequency output signal.

The present disclosure has been made under the circumstances described above and aims to reduce the deterioration in the quality of a radio-frequency output signal.

According to an aspect of the present disclosure, a Doherty amplifier circuit includes: a carrier amplifier that amplifies a first radio frequency signal; a peaking amplifier that amplifies a second radio frequency signal; a first bias circuit having a first bias control terminal to which a first bias control signal is input, a first bias output terminal from which first bias current or a first bias voltage based on the first bias control signal is output to the carrier amplifier, and a first monitoring terminal from which a first monitoring signal representing a state of the first bias current or the first bias voltage is output; a second bias circuit having a second bias control terminal to which a second bias control signal is input, a second bias output terminal from which second bias current or a second bias voltage based on the second bias control signal is output to the peaking amplifier, and a second monitoring terminal from which a second monitoring signal representing a state of the second bias current or the second bias voltage is output; a first differential amplifier having a first input terminal to which a constant voltage is input, a second input terminal electrically connected to the first monitoring terminal, and an output terminal electrically connected to the first bias control terminal, the first differential amplifier outputting the first bias control signal to the first bias control terminal based on a difference between the first monitoring signal and the constant voltage; a second differential amplifier having a first input terminal electrically connected to the first monitoring terminal and a second input terminal electrically connected to the second monitoring terminal, the second differential amplifier outputting an amplified signal from an output terminal based on a difference between the second monitoring signal and the first monitoring signal; and an inverting amplifier that outputs the second bias control signal to the second bias control terminal, the second bias control signal resulting from inverting amplification of the amplified signal.

According to the present disclosure, the deterioration in the quality of a radio-frequency output signal may be reduced.

### BRIEF DESCRIPTION OF THE DRAWINGS

FIG. 1 is a diagram illustrating the configuration of a Doherty amplifier circuit of a first embodiment;

FIG. 2 is a diagram illustrating the configuration of a Doherty amplifier circuit of a second embodiment;

FIG. 3 is a diagram illustrating the configuration of a Doherty amplifier circuit of a third embodiment;

FIG. 4 is a diagram illustrating the configuration of a Doherty amplifier circuit of a fourth embodiment; and

FIG. 5 is a diagram illustrating the configuration of a Doherty amplifier circuit of a fifth embodiment.

### DETAILED DESCRIPTION

Hereinafter, embodiments of the present disclosure will be described in detail based on the drawings. The embodiments do not limit the present disclosure. It goes without saying that each embodiment is exemplification and configurations illustrated in different embodiments can be partially replaced or combined. After a second embodiment, the description of a matter common to that in a first embodiment is omitted, and one or more different points will only be described. In particular, the same effects and operations of the same configuration are not referred to in each embodiment.

### First Embodiment

### Configuration

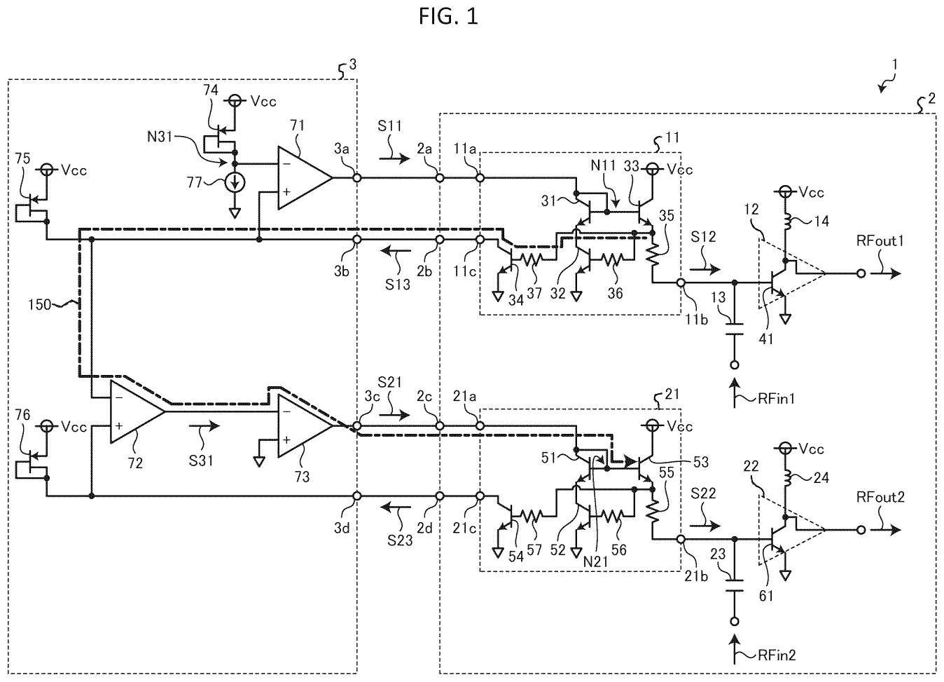

FIG. 1 is a diagram illustrating the configuration of a Doherty amplifier circuit of the first embodiment. A Doherty amplifier circuit 1 includes a first die 2 and a second die 3.

In the embodiment, the first die 2 is a gallium arsenide (GaAs) die, and bipolar transistors are formed in and on the first die 2. A heterojunction bipolar transistor (HBT) is exemplified as the bipolar transistor; however, the present disclosure is not limited to this. The second die 3 is a silicon (Si) die, and field effect transistors (FETs) are formed in and on the second die 3.

The transistor may be a multi-finger transistor in which a plurality of unit transistors are electrically connected in parallel. A unit transistor denotes a minimum configuration of a transistor.

The source of the FET corresponds to the emitter of a bipolar transistor, the gate thereof corresponds to the base of the bipolar transistor, and the drain thereof corresponds to the collector of the bipolar transistor.

The first die 2 has die terminals 2a to 2d. The second die 3 has die terminals 3a to 3d. The die terminal 2a and the die terminal 3a are electrically connected. The die terminal 2b and the die terminal 3b are electrically connected. The die terminal 2c and the die terminal 3c are electrically connected. The die terminal 2d and the die terminal 3d are electrically connected.

The second die 3 outputs a first bias control signal S11 from the die terminal 3a to the die terminal 2a of the first die 2. The first die 2 outputs a first monitoring signal S13 from the die terminal 2b to the die terminal 3b of the second die 3. The second die 3 outputs a second bias control signal S21 from the die terminal 3c to the die terminal 2c of the first die 2. The first die 2 outputs a second monitoring signal S23 from the die terminal 2d to the die terminal 3d of the second die 3. These signals will be described later.

In the embodiment, the first bias control signal S11, the first monitoring signal S13, the second bias control signal S21, and the second monitoring signal S23 are voltage signals; however, the present disclosure is not limited to this.

The first die 2 includes a first bias circuit 11, a carrier amplifier 12, a DC blocking capacitor 13, a choke coil 14, a second bias circuit 21, a peaking amplifier 22, a DC blocking capacitor 23, and a choke coil 24.

The first bias circuit 11 has a first bias control terminal 11a, a first bias output terminal 11b, and a first monitoring terminal 11c.

The first bias control terminal 11a is electrically connected to the die terminal 2a, and the first bias control signal S11 is input from the second die 3.

The first bias output terminal 11b is electrically connected to the carrier amplifier 12. The first bias circuit 11 outputs the first bias current or a first bias voltage S12 based on the first bias control signal S11 from the first bias output terminal 11b to the carrier amplifier 12.

The first monitoring terminal 11c is electrically connected to the die terminal 2b. The first bias circuit 11 outputs the first monitoring signal S13 representing the state of the first bias current or the first bias voltage S12 from the first monitoring terminal 11c to the second die 3.

The first bias circuit 11 includes transistors 31 to 34 that are NPN bipolar transistors and resistors 35 to 37.

The collector and the base of the transistor 31 are respectively electrically connected to the first bias control terminal 11a and a node N11. The emitter of the transistor 31 is electrically connected to the collector of the transistor 32. The emitter of the transistor 32 is electrically connected to the reference potential. The ground potential is exemplified as the reference potential; however, the present disclosure is not limited to this.

The transistor 31 and the transistor 32 cause a potential according to the first bias control signal S11 at the node N11.

The collector of the transistor 33 is electrically connected to a power supply voltage Vcc. The base of the transistor 33 is electrically connected to the node N11. The emitter of the transistor 33 is electrically connected to one end of the resistor 35. The other end of the resistor 35 is electrically connected to the first bias output terminal 11b. That is, the transistor 33 and the resistor 35 are connected in emitter follower configuration. The transistor 33 outputs the first bias current or the first bias voltage S12 according to a potential at the node N11 from the first bias output terminal 11b to the carrier amplifier 12.

The transistor 33 corresponds to an example of a first output transistor of the present disclosure.

One end of the resistor 36 is electrically connected to the emitter of the transistor 33. The other end of the resistor 36 is electrically connected to the base of the transistor 32. The resistor 36 adjusts the potential level of the emitter potential of the transistor 33 and inputs the potential to the base of transistor 32. The first bias circuit 11 thereby has a first negative feedback path from the emitter of the transistor 33, the resistor 36, the base of the transistor 32 to the collector of the transistor 32, the emitter of the transistor 31, the base of the transistor 31, the node N11, and the base of the transistor 33. In other words, the first bias circuit 11 has the first negative feedback path from the emitter of the transistor 33 to the base thereof.

The first bias circuit 11 has the first negative feedback path and thereby raises the base potential of the transistor 33 to compensate for a drop in the voltage between the base and the emitter of the transistor 33. The first bias circuit 11 thus stabilizes the first bias current or the first bias voltage S12 and may reduce a decrease in output from the carrier amplifier 12.

The first negative feedback path is formed by the NPN bipolar transistors. NPN bipolar transistors have electrons as a majority carrier and thus are capable of operating at higher speed than PNP bipolar transistors. Due to the first negative feedback path, the first bias circuit 11 may thus respond quickly to variation in the emitter potential of the transistor 33.

One end of the resistor 37 is electrically connected to the emitter of the transistor 33. The other end of the resistor 37 is electrically connected to the base of the transistor 34. The resistor 37 adjusts the potential level of the emitter potential of the transistor 33 and outputs the potential to the base of the transistor 34.

The emitter of the transistor 34 is electrically connected to the reference potential. The collector of the transistor 34 is electrically connected to the first monitoring terminal 11c. The collector current of the transistor 34 flows through a path from the die terminal 3b to the die terminal 2b, the first monitoring terminal 11c, and the collector of the transistor 34. The collector current of the transistor 34 decreases in response to a drop in the emitter potential of the transistor 33 and increases in response to a rise in the emitter potential of the transistor 33. The collector potential of the transistor 34 rises in response to a decrease in the collector current of the transistor 34 and drops in response to an increase in the collector current of the transistor 34. The collector potential of the transistor 34 corresponds to the first monitoring signal S13.

The carrier amplifier 12 includes a transistor 41 that is a NPN bipolar transistor. The emitter of the transistor 41 is electrically connected to the reference potential. The collector of the transistor 41 is electrically connected to a power supply voltage Vcc with the choke coil 14 interposed therebetween. The base of the transistor 41 is electrically connected to the first bias output terminal 11b, and the first bias current or the first bias voltage S12 is input. A radio frequency signal RFin1 is input to one end of the DC blocking capacitor 13. The other end of the DC blocking capacitor 13 is electrically connected to the base of the transistor 41. The DC blocking capacitor 13 removes the direct-current component of the radio frequency signal RFin1 and outputs the radio frequency signal RFin1 to the base of the transistor 41. The transistor 41 amplifies the radio frequency signal RFin1 and outputs a radio frequency signal RFout1 from the collector.

The second bias circuit 21 has a second bias control terminal 21a, a second bias output terminal 21b, and a second monitoring terminal 21c.

The second bias control terminal 21a is electrically connected to the die terminal 2c, and the second bias control signal S21 is input from the second die 3.

The second bias output terminal 21b is electrically connected to the peaking amplifier 22. The second bias circuit 21 outputs second bias current or a second bias voltage S22 based on the second bias control signal S21 from the second bias output terminal 21b to the peaking amplifier 22.

The second monitoring terminal 21c is electrically connected to the die terminal 2d. The second bias circuit 21 outputs the second monitoring signal S23 representing the state of the second bias current or the second bias voltage S22 from the second monitoring terminal 21c to the second die 3.

The second bias circuit 21 includes transistors 51 to 54 that are NPN bipolar transistors and resistors 55 to 57.

The collector and the base of the transistor 51 are respectively electrically connected to the second bias control terminal 21a and a node N21. The emitter of the transistor 51 is electrically connected to the collector of the transistor 52. The emitter of the transistor 52 is electrically connected to the reference potential.

The transistor 51 and the transistor 52 cause a potential according to the second bias control signal S21 at the node N21.

The collector of the transistor 53 is electrically connected to a power supply voltage Vcc. The base of the transistor 53 is electrically connected to the node N21. The emitter of the transistor 53 is electrically connected to one end of the resistor 55. The other end of the resistor 55 is electrically connected to the second bias output terminal 21b. That is, the transistor 53 and the resistor 55 are connected in emitter follower configuration. The transistor 53 outputs the second bias current or the second bias voltage S22 according to a potential at the node N21 from the second bias output terminal 21b to the peaking amplifier 22.

The transistor 53 corresponds to an example of a second output transistor of the present disclosure.

One end of the resistor 56 is electrically connected to the emitter of the transistor 53. The other end of the resistor 56 is electrically connected to the base of the transistor 52. The resistor 56 adjusts the potential level of the emitter potential of the transistor 53 and inputs the potential to the base of the transistor 52. The second bias circuit 21 thereby has a second negative feedback path from the emitter of the transistor 53 to the resistor 56, the base of the transistor 52, the collector of the transistor 52, the emitter of the transistor 51, the base of the transistor 51, the node N21, and the base of the transistor 53. In other words, the second bias circuit 21 has the second negative feedback path from the emitter of the transistor 53 to the base thereof.

The second bias circuit 21 has the second negative feedback path and thereby raises the base potential of the transistor 33 to compensate for a drop in the voltage between the base and the emitter of the transistor 53. The second bias circuit 21 thus stabilizes the second bias current or the second bias voltage S22 and may reduce a decrease in output from the peaking amplifier 22.

The second negative feedback path is formed by the NPN bipolar transistors. NPN bipolar transistors have electrons as a majority carrier and thus are capable of operating at higher speed than PNP bipolar transistors. Due to the second negative feedback path, the second bias circuit 21 may thus respond quickly to variation in the emitter potential of the transistor 53.

One end of the resistor 57 is electrically connected to the emitter of the transistor 53. The other end of the resistor 57 is electrically connected to the base of the transistor 54. The resistor 57 adjusts the potential level of the emitter potential of the transistor 53 and outputs the potential to the base of the transistor 54.

The emitter of the transistor 54 is electrically connected to the reference potential. The collector of the transistor 54 is electrically connected to the second monitoring terminal 21c. The collector current of the transistor 54 flows through a path from the die terminal 2d to the die terminal 3d, the second monitoring terminal 21c, and the collector of the transistor 54. The collector current of the transistor 54 increases in response to a rise in the emitter potential of the transistor 53 and decreases in response to a drop in the emitter potential of the transistor 53. The collector potential of the transistor 54 rises in response to a decrease in the collector current of the transistor 54 and drops in response to an increase in the collector current of the transistor 54. The collector potential of the transistor 54 corresponds to the second monitoring signal S23.

The peaking amplifier 22 includes a transistor 61 that is a NPN bipolar transistor. The emitter of the transistor 61 is electrically connected to the reference potential. The collector of the transistor 61 is electrically connected to the power supply voltage Vcc with the choke coil 24 interposed therebetween. The base of the transistor 61 is electrically connected to the second bias output terminal 21b, and the second bias current or the second bias voltage S22 is input. A radio frequency signal RFin2 is input to one end of the DC blocking capacitor 23. The other end of the DC blocking capacitor 23 is electrically connected to the base of the transistor 61. The DC blocking capacitor 23 removes the direct-current component of the radio frequency signal RFin2 and outputs the radio frequency signal RFin2 to the base of the transistor 61. The transistor 61 amplifies the radio frequency signal RFin2 and outputs a radio frequency signal RFout2 from the collector.

The second die 3 includes a first differential amplifier 71, a second differential amplifier 72, a third differential amplifier 73, transistors 74 to 76 that are P-channel-type FETs, and a constant current source 77. The first differential amplifier 71, the second differential amplifier 72, and the third differential amplifier 73 are formed by FETs.

The source of the transistor 74 is electrically connected to a power supply voltage Vcc. The gate and the drain of the transistor 74 are electrically connected to a node N31. That is, the transistor 74 is diode-connected. One end of the constant current source 77 is electrically connected to the node N31. The other end of the constant current source 77 is electrically connected to the reference potential. The transistor 74 and the constant current source 77 cause constant potential to be generated at the node N31.

The source of the transistor 75 is electrically connected to a power supply voltage Vcc. The gate and the drain of the transistor 75 are electrically connected to the die terminal 3b. That is, the transistor 75 is diode-connected. A voltage across the die terminal 3b rises in response to a decrease in the collector current of the transistor 34 and drops in response to an increase in the collector current of the transistor 34.

The source of the transistor 76 is electrically connected to a power supply voltage Vcc. The gate and the drain of the transistor 76 are electrically connected to the die terminal 3d. That is, the transistor 76 is diode-connected. A voltage across the die terminal 3d rises in response to a decrease in the collector current of the transistor 54 and drops in response to an increase in the collector current of the transistor 54.

The inverting input terminal (negative terminal) of the first differential amplifier 71 is electrically connected to the node N31. The non-inverting input terminal (positive terminal) of the first differential amplifier 71 is electrically connected to the die terminal 3b. The output terminal of the first differential amplifier 71 is electrically connected to the die terminal 3a.

The inverting input terminal (negative terminal) of the first differential amplifier 71 corresponds to an example of a first input terminal of the present disclosure. The non-inverting input terminal (positive terminal) of the first differential amplifier 71 corresponds to an example of a second input terminal of the present disclosure.

Based on a difference between the first monitoring signal S13 and the constant potential at the node N31, the first differential amplifier 71 outputs the first bias control signal S11 from the die terminal 3a to the die terminal 2a of the first die 2. The Doherty amplifier circuit 1 thereby has a third negative feedback path from the emitter of the transistor 33 to the resistor 37, the base of the transistor 34, the collector of the transistor 34, the non-inverting input terminal of the first differential amplifier 71, the output terminal of the first differential amplifier 71, the node N11, and the base of the transistor 33.

The Doherty amplifier circuit 1 has the third negative feedback path and thereby raises the base potential of the transistor 33 to compensate for the drop in the voltage between the base and the emitter of the transistor 33. The Doherty amplifier circuit 1 thus stabilizes the first bias current or the first bias voltage S12 and may reduce the decrease in output from the carrier amplifier 12.

The third negative feedback path is formed by the first differential amplifier 71. The first differential amplifier 71 has considerably higher gain sensitivity than, for example, a general single-ended amplifier. Due to the third negative feedback path, the Doherty amplifier circuit 1 may thus respond highly sensitively to the variation in the emitter potential of the transistor 33.

The inverting input terminal (negative terminal) of the second differential amplifier 72 is electrically connected to the die terminal 3b. The non-inverting input terminal (positive terminal) of the second differential amplifier 72 is electrically connected to the die terminal 3d. The output terminal of the second differential amplifier 72 is electrically connected to the inverting input terminal (negative terminal) of the third differential amplifier 73.

The inverting input terminal (negative terminal) of the second differential amplifier 72 corresponds to an example of a first input terminal of the present disclosure. The non-inverting input terminal (positive terminal) of the second differential amplifier 72 corresponds to an example of a second input terminal of the present disclosure.

Based on a difference between the first monitoring signal S13 and the second monitoring signal S23, the second differential amplifier 72 outputs an amplified signal S31 to the inverting input terminal (negative terminal) of the third differential amplifier 73.

The non-inverting input terminal (positive terminal) of the third differential amplifier 73 is electrically connected to the reference potential. That is, the third differential amplifier 73 is an inverting amplifier. The output terminal of the third differential amplifier 73 is electrically connected to the die terminal 3c.

The inverting input terminal (negative terminal) of the third differential amplifier 73 corresponds to an example of a first input terminal of the present disclosure. The non-inverting input terminal (positive terminal) of the third differential amplifier 73 corresponds to an example of a second input terminal of the present disclosure.

Based on a difference between the reference potential and the amplified signal S31, the third differential amplifier 73 outputs the second bias control signal S21 from the die terminal 3c to the die terminal 2c of the first die 2. The Doherty amplifier circuit 1 thereby has a fourth negative feedback path from the emitter of the transistor 53 to the resistor 57, the base of the transistor 54, the collector of the transistor 54, the non-inverting input terminal of the second differential amplifier 72, the output terminal of the second differential amplifier 72, the output terminal of the third differential amplifier 73, the node N21, and the base of the transistor 53.

The Doherty amplifier circuit 1 has the fourth negative feedback path and thereby raises the base potential of the transistor 53 to compensate for the drop in the voltage between the base and the emitter of the transistor 53. The Doherty amplifier circuit 1 thus stabilizes the second bias current or the second bias voltage S22 and may reduce the decrease in output from the peaking amplifier 22.

The fourth negative feedback path includes the second differential amplifier 72 and the third differential amplifier 73. The second differential amplifier 72 and the third differential amplifier 73 have considerably higher gain and sensitivity than, for example, a general single-ended amplifier. Due to the fourth negative feedback path, the Doherty amplifier circuit 1 may thus respond highly sensitively to the variation in the emitter potential of the transistor 53.

### Operations at Rise in Drive Level of Carrier Amplifier

When the drive level of the carrier amplifier 12 rises (approaches saturation), and when the base potential of the transistor 41 drops, the emitter potential of the transistor 33 drops, the base potential of the transistor 34 drops, the collector current of the transistor 34 decreases, and the potential at the first monitoring terminal 11c rises. In other words, the first monitoring signal S13 representing the state of the first bias current or the first bias voltage supplied to the carrier amplifier 12 is output from the first monitoring terminal 11c.

The first monitoring terminal 11c is electrically connected to the non-inverting input terminal (positive terminal) of the first differential amplifier 71. Accordingly, a rise in the drive level of the carrier amplifier 12 causes the voltage of the first bias control signal S11 to rise, the potential at the node N11 to rise, and a drop in the base potential of the transistor 33 to be reduced. In other words, the first bias current or the first bias voltage based on the first bias control signal S11 is output from the transistor 33 in the first bias circuit 11 to the carrier amplifier 12. This reduces the drop in the emitter potential of the transistor 33 and the decrease in output from the carrier amplifier 12.

The first monitoring terminal 11c is electrically connected to the inverting input terminal (negative terminal) of the second differential amplifier 72. A rise in the drive level of the carrier amplifier 12 causes the voltage of the amplified signal S31 to drop. The third differential amplifier 73 is an inverting amplifier. Accordingly, a rise in the drive level of the carrier amplifier 12 causes the voltage of the second bias control signal S21 to rise, the potential at the node N21 to rise, and the base potential of the transistor 53 to rise.

As described above, if the emitter potential of the transistor 33 drops, the Doherty amplifier circuit 1 raises the base potential of the transistor 53 by using a path 150 from the emitter of the transistor 33 to the resistor 37, the base of the transistor 34, the collector of the transistor 34, the inverting input terminal of the second differential amplifier 72, the output terminal of the second differential amplifier 72, the inverting input terminal of the third differential amplifier 73, the output terminal of the third differential amplifier 73, the node N21, and the base of the transistor 53 and activates the peaking amplifier 22.

### Effects

The path 150 includes the second differential amplifier 72 and the third differential amplifier 73. The second differential amplifier 72 and the third differential amplifier 73 have considerably high gain and sensitivity.

The Doherty amplifier circuit 1 may thus detect a slight drop in the emitter potential of the transistor 33 highly sensitively and activate the peaking amplifier 22. The Doherty amplifier circuit 1 thereby reduces the deterioration in the quality of a radio-frequency output signal resulting from the combination of the radio frequency signal RFout1 and the radio frequency signal RFout2.

The first negative feedback path is formed by the bipolar transistors. Bipolar transistors are capable of operating at higher speed than FETs. The third negative feedback path includes the first differential amplifier 71. The first differential amplifier 71 has considerably high gain and sensitivity.

The Doherty amplifier circuit 1 may thus respond quickly to the variation in the emitter potential of the transistor 33 due to the first negative feedback path and may also respond highly sensitively to the variation due to the third negative feedback path. In other words, the Doherty amplifier circuit 1 may reduce the drop in the base potential of the transistor 33 quickly and highly sensitively due to both of the first negative feedback path and the third negative feedback path when the emitter potential of the transistor 33 drops. Even if the drive level of the carrier amplifier 12 rises (approaches saturation), the Doherty amplifier circuit 1 may thereby reduce the decrease in output from the carrier amplifier 12 and thus reduce the deterioration in the quality of the radio frequency signal RFout1.

The second negative feedback path is formed by the bipolar transistors. Bipolar transistors are capable of operating at higher speed than FETs. The fourth negative feedback path includes the second differential amplifier 72 and the third differential amplifier 73. The second differential amplifier 72 and the third differential amplifier 73 have considerably high gain and sensitivity.

The Doherty amplifier circuit 1 may thus respond quickly to the variation in the emitter potential of the transistor 53 due to the second negative feedback path and may also respond highly sensitively to the variation due to the fourth negative feedback path. In other words, the Doherty amplifier circuit 1 may reduce a drop in the base potential of the transistor 53 quickly and highly sensitively due to both of the second negative feedback path and the fourth negative feedback path when the emitter potential of the transistor 53 drops. The Doherty amplifier circuit 1 may thereby reduce the decrease in output from the peaking amplifier 22 when the state of the peaking amplifier 22 approaches the saturation state and thus reduce the deterioration in the quality of the radio frequency signal RFout2.

### Second Embodiment

### Configuration

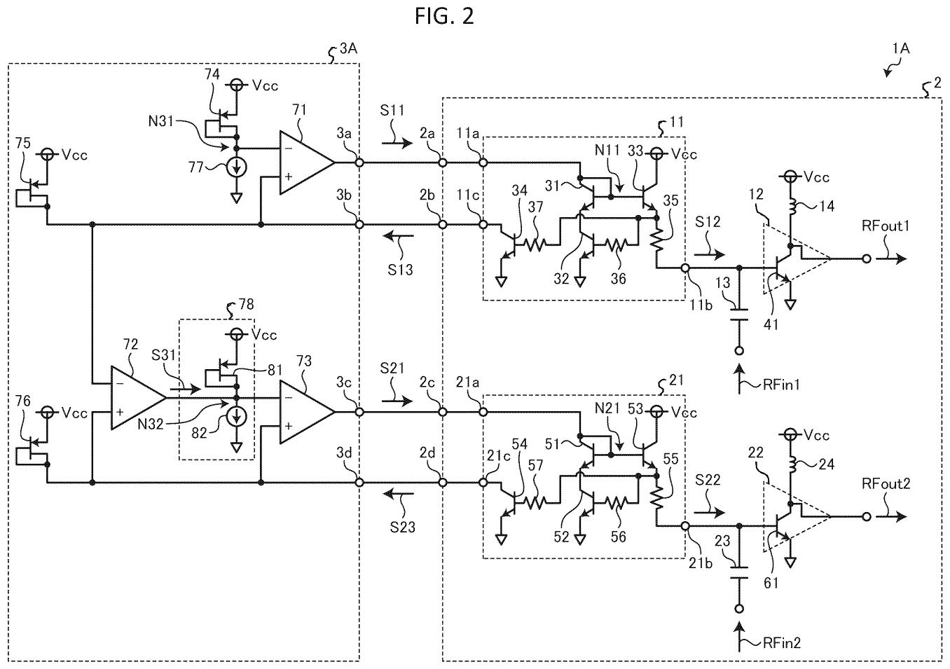

FIG. 2 is a diagram illustrating the configuration of a Doherty amplifier circuit of the second embodiment.

As compared with the Doherty amplifier circuit 1 (see FIG. 1), a Doherty amplifier circuit 1A includes a second die 3A, instead of the second die 3.

In the second embodiment, the non-inverting input terminal (positive terminal) of the third differential amplifier 73 is electrically connected to the die terminal 3d, and the second monitoring signal S23 is input.

As compared with the second die 3, the second die 3A further includes a potential level adjustment circuit 78.

The potential level adjustment circuit 78 includes a transistor 81 that is a P-channel-type FET and a constant current source 82. The source of the transistor 81 is electrically connected to a power supply voltage Vcc. The gate and the drain of the transistor 81 are electrically connected to a node N32. That is, the transistor 81 is diode-connected. One end of the constant current source 82 is electrically connected to the node N32. The other end of the constant current source 82 is electrically connected to the reference potential. The transistor 81 and the constant current source 82 cause constant potential to be generated at the node N32.

The potential level adjustment circuit 78 adjusts the amount of current of the constant current source 82 and thereby adjusts the potential level of the amplified signal S31 to the potential level of the second monitoring signal S23. The potential level of the second monitoring signal S23 herein not only denotes the same potential level as the potential level of the second monitoring signal S23 but also includes a potential level (a potential level to the similar extent) slightly deviating from the potential level of the second monitoring signal S23.

### Effects

The Doherty amplifier circuit 1A has a fifth negative feedback path from the emitter of the transistor 53 to the resistor 57, the base of the transistor 54, the collector of the transistor 54, the non-inverting input terminal of the third differential amplifier 73, the output terminal of the third differential amplifier 73, the node N21, and the base of the transistor 53. The third differential amplifier 73 has considerably high gain and sensitivity.

The Doherty amplifier circuit 1A may thus reduce a decrease in the base potential of the transistor 53 more reliably and enhance the effect of the negative feedback, that is, reduction in the decrease in output from the peaking amplifier 22.

### Third Embodiment

### Configuration

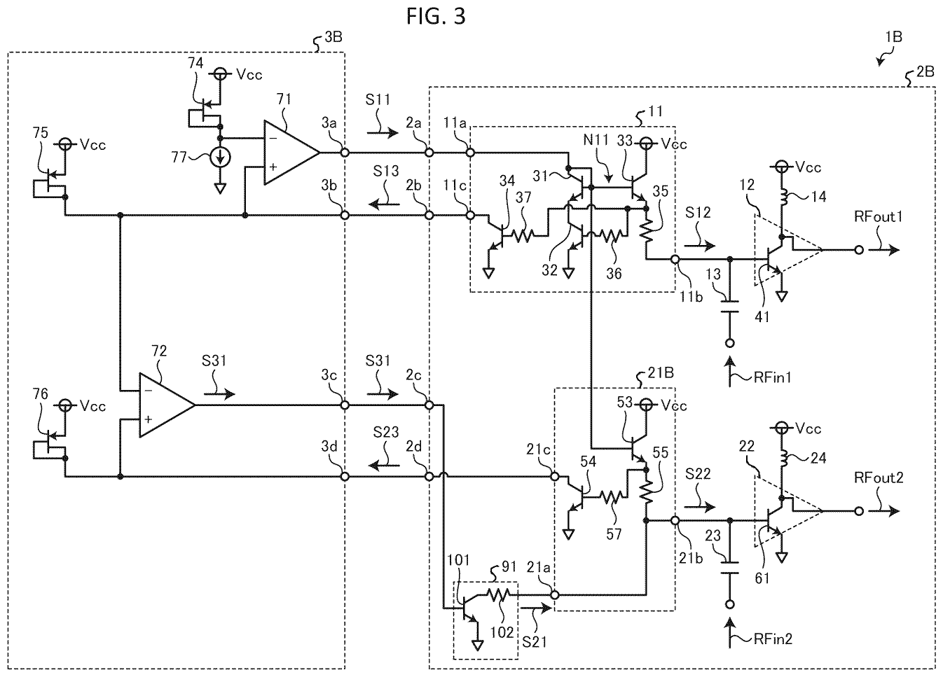

FIG. 3 is a diagram illustrating the configuration of a Doherty amplifier circuit of a third embodiment.

As compared with the Doherty amplifier circuit 1 (see FIG. 1), a Doherty amplifier circuit 1B includes a first die 2B, instead of the first die 2. The Doherty amplifier circuit 1B also includes a second die 3B, instead of the second die 3.

As compared with the second die 3, the second die 3B does not include the third differential amplifier 73. The second differential amplifier 72 outputs the amplified signal S31 from the die terminal 3c to the die terminal 2c of the first die 2B.

As compared with the first die 2, the first die 2B includes a second bias circuit 21B, instead of the second bias circuit 21. The first die 2B further includes an inverting amplifier 91.

As compared with the second bias circuit 21, the second bias circuit 21B does not include the transistor 51, the transistor 52, and the resistor 56. The base of the transistor 53 is electrically connected to the node N11 in the first bias circuit 11.

The inverting amplifier 91 inverts the amplified signal S31 and outputs the second bias control signal S21 to the second bias control terminal 21a. The second bias control terminal 21a is electrically connected to the other end of the resistor 55.

The inverting amplifier 91 includes a transistor 101 and a resistor 102.

The emitter of the transistor 101 is electrically connected to the reference potential. The base of the transistor 101 is electrically connected to the die terminal 2c, and the amplified signal S31 is input. The collector of the transistor 101 is electrically connected to one end of the resistor 102. The other end of the resistor 102 is electrically connected to the other end of the resistor 55.

If the base potential (amplified signal S31) drops in the transistor 101, collector current decreases. This causes the potential at the die terminal 2c to rise. If the base potential (amplified signal S31) rises in the transistor 101, the collector current increases. This causes the emitter voltage of the transistor 53 to drop.

### Operations

Typically, in a carrier amplifier, high base current is required as a drive level becomes high, and a voltage between the base and the emitter of the output transistor in the carrier bias circuit becomes high. This causes the output power from the carrier bias circuit to decrease.

However, the first bias circuit 11 of the embodiment has the first negative feedback path described above and thereby supplies the stable first bias current or the stable first bias voltage S12 to the carrier amplifier 12. This is because the first negative feedback path operates to compensate for a drop in the voltage between the base and the emitter of the transistor 33. That is, the first bias circuit 11 has the first negative feedback path, and thereby the base potential of the transistor 33 (the potential at the node N11) rises with the rise in the drive level of the carrier amplifier 12.

By inputting the rising potential at the node N11 to the base of the transistor 53, the second bias circuit 21B raises not only the drive level of the carrier amplifier 12 but also the second bias current or the second bias voltage S22 and may activate the peaking amplifier 22. The operation is implementable by only bipolar transistors. Bipolar transistors are capable of operating at higher speed than FETs. The second bias circuit 21B may thus activate the peaking amplifier 22 quickly in response to a rise in the drive level of the carrier amplifier 12.

If the drive level of the carrier amplifier 12 rises, the voltage of the amplified signal S31 that is an output signal from the second differential amplifier 72 drops. This causes the base potential of the transistor 101 to drop and the collector current of the transistor 101 to decrease. As the result of this, reduction in the voltage drop at the resistor 55 due to the collector current of the transistor 101 causes the base potential of the transistor 61 of the peaking amplifier 22 to rise, and thus the peaking amplifier 22 is activated. The operation is implementable by using the second differential amplifier 72. The second differential amplifier 72 has considerably high gain and sensitivity. The Doherty amplifier circuit 1B may thus activate the peaking amplifier 22 highly sensitively in response to the rise in the drive level of the carrier amplifier 12.

### Effects

The Doherty amplifier circuit 1B may activate the peaking amplifier 22 quickly and highly sensitively in response to the rise in the drive level of the carrier amplifier 12.

### Fourth Embodiment

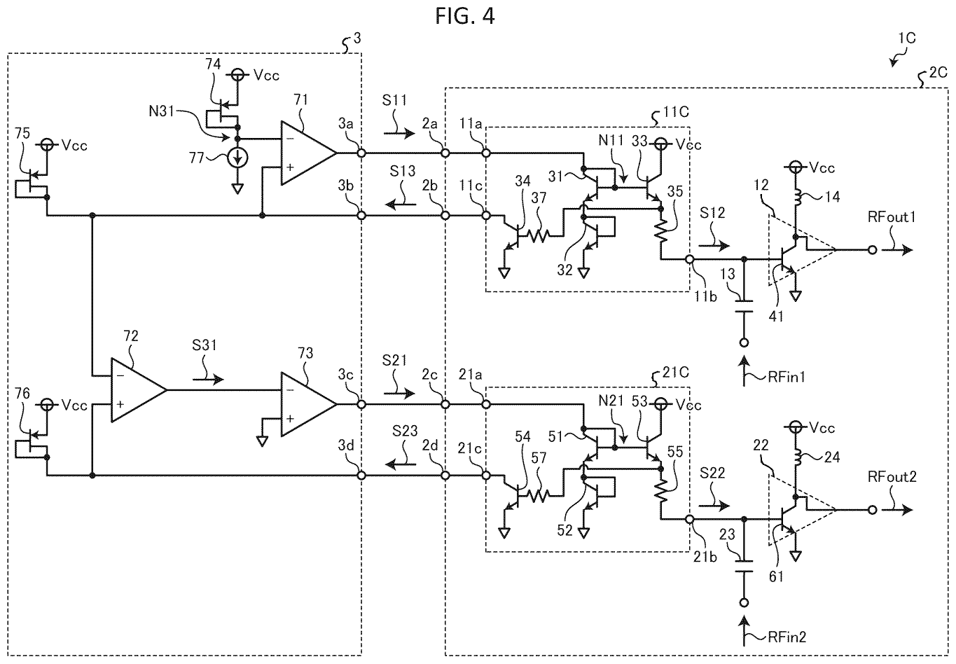

FIG. 4 is a diagram illustrating the configuration of a Doherty amplifier circuit of a fourth embodiment.

As compared with the Doherty amplifier circuit 1 (see FIG. 1), a Doherty amplifier circuit 1C includes a first die 2C, instead of the first die 2.

As compared with the first die 2, the first die 2C includes a first bias circuit 11C, instead of the first bias circuit 11. The first die 2C also includes a second bias circuit 21C, instead of the second bias circuit 21.

As compared with the first bias circuit 11, the first bias circuit 11C does not include the resistor 36. The base of the transistor 32 is electrically connected to the collector. That is, the transistor 32 is diode-connected. Accordingly, as compared with the first bias circuit 11, the first bias circuit 11C does not have the first negative feedback path.

However, like the Doherty amplifier circuit 1, the Doherty amplifier circuit 1C has the third negative feedback path. The Doherty amplifier circuit 1C may thus reduce the drop in the base potential of the transistor 33, stabilize the first bias current or the first bias voltage S12, reduce the decrease in output from the carrier amplifier 12, and reduce the deterioration in the quality of the radio frequency signal RFout1.

As compared with the second bias circuit 21, the second bias circuit 21C does not include the resistor 56. The base of the transistor 52 is electrically connected to the collector. That is, the transistor 52 is diode-connected. Accordingly, as compared with the second bias circuit 21, the second bias circuit 21C does not have the second negative feedback path.

However, like the Doherty amplifier circuit 1, the Doherty amplifier circuit 1C has the fourth negative feedback path. The Doherty amplifier circuit 1C may thus reduce the drop in the base potential of the transistor 53, stabilize the second bias current or the second bias voltage S22, reduce the decrease in output from the peaking amplifier 22, and reduce the deterioration in the quality of the radio frequency signal RFout2.

### Fifth Embodiment

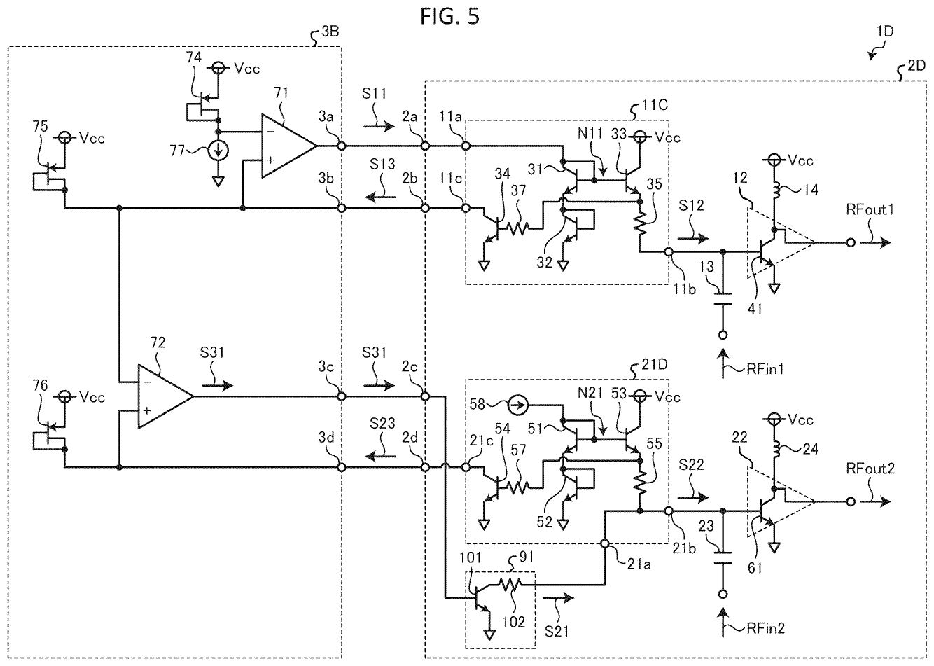

FIG. 5 is a diagram illustrating the configuration of a Doherty amplifier circuit of a fifth embodiment.

As compared with the Doherty amplifier circuit 1B (see FIG. 3), a Doherty amplifier circuit 1D includes a first die 2D, instead of the first die 2B.

As compared with the first die 2C (see FIG. 4), the first die 2D includes a second bias circuit 21D, instead of the second bias circuit 21C.

As compared with the second bias circuit 21C, the second bias circuit 21D further includes a constant current source 58.

The node N21 in the second bias circuit 21D is not electrically connected to the second bias control terminal 21a. Instead, the constant current source 58 is electrically connected to the node N21. The constant current source 58 outputs constant current to the node N21. The transistor 51 and the transistor 52 cause a potential according to the constant current output from the constant current source 58 to be generated at the node N21. The other end of the resistor 55 is electrically connected to the second bias control terminal 21a.

The second bias circuit 21D does not have the second negative feedback path. However, like the Doherty amplifier circuit 1, the Doherty amplifier circuit 1D has the fourth negative feedback path. The Doherty amplifier circuit 1D may thus reduce the drop in the base potential of the transistor 53, stabilize the second bias current or the second bias voltage S22, reduce the decrease in output from the peaking amplifier 22, and reduce the deterioration in the quality of the radio frequency signal RFout2.

### Example Configuration of Present Disclosure

The present disclosure may also have the following configuration.

(1) A Doherty amplifier circuit of an aspect of the present disclosure comprising: a carrier amplifier that amplifies a first radio frequency signal,
a peaking amplifier that amplifies a second radio frequency signal,
a first bias circuit having a first bias control terminal to which a first bias control signal is input, a first bias output terminal from which first bias current or a first bias voltage based on the first bias control signal is output to the carrier amplifier, and a first monitoring terminal from which a first monitoring signal representing a state of the first bias current or the first bias voltage is output,
a second bias circuit having a second bias control terminal to which a second bias control signal is input, a second bias output terminal from which second bias current or a second bias voltage based on the second bias control signal is output to the peaking amplifier, and a second monitoring terminal from which a second monitoring signal representing a state of the second bias current or the second bias voltage is output,
a first differential amplifier having a first input terminal to which a constant voltage is input, a second input terminal electrically connected to the first monitoring terminal, and an output terminal electrically connected to the first bias control terminal, the first differential amplifier outputting the first bias control signal to the first bias control terminal based on a difference between the first monitoring signal and the constant voltage,
a second differential amplifier having a first input terminal electrically connected to the first monitoring terminal and a second input terminal electrically connected to the second monitoring terminal, the second differential amplifier outputting an amplified signal from an output terminal based on a difference between the second monitoring signal and the first monitoring signal,
an inverting amplifier that outputs the second bias control signal to the second bias control terminal, the second bias control signal resulting from inverting amplification of the amplified signal.

(2) In the Doherty amplifier circuit according to (1) above,
the inverting amplifier is
   a third differential amplifier having a first input terminal electrically connected to the output terminal of the second differential amplifier, a second input terminal electrically connected to a reference potential, and an output terminal electrically connected to the second bias control terminal.

(3) In the Doherty amplifier circuit according to (1) above,
the inverting amplifier is
   a third differential amplifier having a first input terminal electrically connected to the output terminal of the second differential amplifier, a second input terminal electrically connected to the second monitoring terminal, and an output terminal electrically connected to the second bias control terminal.

(4) The Doherty amplifier circuit according to (3) above further includes:
a potential level adjustment circuit that is electrically connected between the output terminal of the second differential amplifier and the first input terminal of the third differential amplifier and that adjusts a potential level of the amplified signal to a potential level of the second monitoring signal.

(5) In the Doherty amplifier circuit according to (1) above,
the inverting amplifier includes
   a transistor having a base or a gate to which the amplified signal is input, a collector or a drain electrically connected to the second bias control terminal, and an emitter or a source electrically connected to a reference potential.

(6) In the Doherty amplifier circuit according to any one of (1) to (5) above,
the first bias circuit
   includes a first output transistor from which the first bias current or the first bias voltage is output and has a first negative feedback path from an emitter or a source of the first output transistor to a base or a gate of the first output transistor.

(7) In the Doherty amplifier circuit according to any one of (1) to (6) above,
the second bias circuit
   includes a second output transistor that outputs the second bias current or the second bias voltage and has a second negative feedback path from an emitter or a source of the second output transistor to a base or a gate of the second output transistor.

(8) In the Doherty amplifier circuit according to any one of (1) to (7) above,
the second bias circuit
   includes a second output transistor that outputs the second bias current or the second bias voltage and that has a base or a gate electrically connected to the base or the gate of the first output transistor.

The embodiments described above have been provided for easier understanding of the present disclosure and are not intended to limit the interpretation of the present disclosure. The present disclosure may be changed/improved without departing from the spirit thereof and includes its equivalents.

What is claimed is:

1. A Doherty amplifier circuit comprising:
a carrier amplifier configured to amplify a first radio frequency signal;
a peaking amplifier configured to amplify a second radio frequency signal;
a first bias circuit having a first bias control terminal to which a first bias control signal is input, a first bias output terminal configured to output a first bias current or a first bias voltage based on the first bias control signal to the carrier amplifier, and a first monitoring terminal configured to output a first monitoring signal representing a state of the first bias current or the first bias voltage;
a second bias circuit having a second bias control terminal to which a second bias control signal is input, a second bias output terminal configured to output second bias current or a second bias voltage based on the second bias control signal to the peaking amplifier, and a second monitoring terminal configured to output a second monitoring signal representing a state of the second bias current or the second bias voltage;
a first differential amplifier having a first input terminal to which a constant voltage is input, a second input terminal electrically connected to the first monitoring terminal, and an output terminal electrically connected to the first bias control terminal, the first differential amplifier configured to output the first bias control signal to the first bias control terminal based on a difference between the first monitoring signal and the constant voltage;
a second differential amplifier having a first input terminal electrically connected to the first monitoring terminal and a second input terminal electrically connected to the second monitoring terminal, the second differential amplifier configured to output an amplified signal from an output terminal based on a difference between the second monitoring signal and the first monitoring signal; and
an inverting amplifier configured to output the second bias control signal to the second bias control terminal,
wherein the second bias control signal is based on the inverting amplification of the amplified signal.

2. The Doherty amplifier circuit according to claim 1,
wherein the inverting amplifier is a third differential amplifier having a first input terminal electrically connected to the output terminal of the second differential amplifier, a second input terminal electrically connected to a reference potential, and an output terminal electrically connected to the second bias control terminal.

3. The Doherty amplifier circuit according to claim 1,
wherein the inverting amplifier is a third differential amplifier having a first input terminal electrically connected to the output terminal of the second differential amplifier, a second input terminal electrically connected to the second monitoring terminal, and an output terminal electrically connected to the second bias control terminal.

4. The Doherty amplifier circuit according to claim 3, further comprising:
a potential level adjustment circuit that is electrically connected between the output terminal of the second differential amplifier and the first input terminal of the third differential amplifier, and that is configured to adjust a potential level of the amplified signal to a potential level of the second monitoring signal.

5. The Doherty amplifier circuit according to claim 1,
wherein the inverting amplifier comprises a transistor having a base or a gate to which the amplified signal is input, a collector or a drain electrically connected to the second bias control terminal, and an emitter or a source electrically connected to a reference potential.

6. The Doherty amplifier circuit according to claim 1,
wherein the first bias circuit comprises a first output transistor configured to output the first bias current or the first bias voltage, and has a first negative feedback path from an emitter or a source of the first output transistor to a base or a gate of the first output transistor.

7. The Doherty amplifier circuit according to claim 6,
wherein the second bias circuit comprises a second output transistor configured to output the second bias current or the second bias voltage, and has a second negative feedback path from an emitter or a source of the second output transistor to a base or a gate of the second output transistor.

8. The Doherty amplifier circuit according to claim 6,
wherein the second bias circuit comprises a second output transistor configured to output the second bias current or the second bias voltage and that has a base or a gate electrically connected to the base or the gate of the first output transistor.

9. The Doherty amplifier circuit according to claim 2,
wherein the first bias circuit comprises a first output transistor configured to output the first bias current or the first bias voltage, and has a first negative feedback path from an emitter or a source of the first output transistor to a base or a gate of the first output transistor.

10. The Doherty amplifier circuit according to claim 3,
wherein the first bias circuit comprises a first output transistor configured to output the first bias current or the first bias voltage, and has a first negative feedback path from an emitter or a source of the first output transistor to a base or a gate of the first output transistor.

11. The Doherty amplifier circuit according to claim 4,
wherein the first bias circuit comprises a first output transistor configured to output the first bias current or the first bias voltage, and has a first negative feedback path from an emitter or a source of the first output transistor to a base or a gate of the first output transistor.

12. The Doherty amplifier circuit according to claim 5,
wherein the first bias circuit comprises a first output transistor configured to output the first bias current or the first bias voltage, and has a first negative feedback path from an emitter or a source of the first output transistor to a base or a gate of the first output transistor.
